(19) United States
(12) Patent Application Publication
(10) Pub. No.: US 2014/0021333 A1
(43) Pub. Date: Jan. 23, 2014

(54) IMAGE SENSING APPARATUS

(71) Applicants: Wei-Chou Chen, Hsinchu City (TW); Tsung-Yen Hsieh, Taichung City (TW); Chia-Hung Yeh, Changhua County (TW); Lin Wu, Hubei (CN); Peng-Fei Lee, Henan (CN); Chong-Yang Fang, Taichung City (TW)

(72) Inventors: Wei-Chou Chen, Hsinchu City (TW); Tsung-Yen Hsieh, Taichung City (TW); Chia-Hung Yeh, Changhua County (TW); Lin Wu, Hubei (CN); Peng-Fei Lee, Henan (CN); Chong-Yang Fang, Taichung City (TW)

(73) Assignees: WINTEK CORPORATION, Taichung City (TW); DONGGUAN MASSTOP LIQUID CRYSTAL DISPLAY CO., LTD., Guangdong Province (CN)

(21) Appl. No.: 13/945,932

(22) Filed: Jul. 19, 2013

(30) Foreign Application Priority Data
Jul. 20, 2012 (TW) 101126334

(51) Int. Cl. H01L 27/146

(52) U.S. Cl. CPC H01L 27/14625
USPC 250/208.1

(57) ABSTRACT

An image sensing apparatus including an image sensor and a light transmission module is provided. The image sensor has an active surface including a first sensing area and a second sensing area. The light transmission module is disposed over the active surface, and has a first light transmission area and a second light transmission area. A first light is allowed to penetrate through the first light transmission area and received by the first sensing area. A second light is reflected by the second light transmission area and received by the second sensing area.

### CROSS-REFERENCE TO RELATED APPLICATION

This application claims the priority benefit of Taiwan application serial no. 101126334, filed on Jul. 20, 2012. The entirety of the above-mentioned patent application is hereby incorporated by reference herein and made a part of this specification.

### BACKGROUND OF THE INVENTION

1. Field of the Invention

The invention is related to a sensing apparatus, and more particularly, to an image sensing apparatus.

2. Description of Related Art

With the progress in the manufacturing process of electronic device and photoelectric technology, electronic devices with image sensing apparatus, such as digital camera or digital monitor, are commonly seen in people's daily lives in modern society. In general, this type of image sensing apparatus often uses a charge couple device (CCD) or a complementary metal oxide semiconductor (CMOS) image sensor to receive a transmitted light, sense an image, and provide the image to a back-end device for related image processing.

However, the conventional image sensing apparatus can only receive light on a single direction. Therefore, the images that can be obtained are limited. In order for an electronic device to obtain images on a plurality of directions, a plurality of image sensing apparatus need to be installed, or a rotating apparatus needs to be used to rotate the electronic device and obtain images on different directions. However, use of a plurality of image sensing apparatus on an electronic device may correspondingly increase the cost of hardware and cause additional expense. Even though images on different directions may be obtained by an electronic device mounted on a rotating apparatus, the images are not obtained simultaneously. Thus, how to simultaneously obtain images on a plurality of directions for a single image sensing apparatus is still an issue that people skilled in the art need to actively devote their effort to and solve.

### SUMMARY OF THE INVENTION

The invention provides an image sensing apparatus having a light transmission module to receive lights on a plurality of directions and sense images on a plurality of directions.

The invention provides an image sensing apparatus which includes an image sensor and a light transmission module. The image sensor has an active surface which includes a first sensing area and a second sensing area. The light transmission module is disposed on the active surface, and has a first light transmission area and a second light transmission area. A first light is allowed to penetrate through the first light transmission area and received by the first sensing area. A second light is reflected by the second light transmission area and received by the second sensing area.

In an embodiment of the invention, the light transmission module includes a first medium, a second medium, and a light reflecting layer. The first medium is disposed in the first light transmission area, and the second medium is disposed in the second light transmission area. The light reflecting layer is positioned between the first light transmission area and the second light transmission area.

In an embodiment of the invention, the second light transmission area of the light transmission module reflects the second light via the light reflecting layer in order for the second light to be received by the second sensing area.

In an embodiment of the invention, the light reflecting layer tilts at an angle relative to the active surface, and the angle is not a right angle.

In an embodiment of the invention, the light reflecting layer is a light reflecting coating.

In an embodiment of the invention, the first medium includes a solid medium or a gaseous medium, and the second medium includes a solid medium or a gaseous medium.

In an embodiment of the invention, the image sensing apparatus further includes a lens set, which is disposed on a transmitting path of the second light. The second medium is positioned between the lens set and the light reflecting layer.

In an embodiment of the invention, the image sensing apparatus further includes a lens set, which is disposed on a transmitting path of the first light, and the light transmission module is positioned between the lens set and the image sensor.

In an embodiment of the invention, the image sensing apparatus further includes a lens set, which is disposed between the image sensor and the light transmission module, and the lens set is positioned on transmitting paths of the first light and the second light.

In an embodiment of the invention, the image sensor of the image sensing apparatus includes a charge coupled device or a complementary metal oxide semiconductor image sensor.

Based on the above, the image sensing apparatus provided in the embodiments of the invention uses the first light transmission area, the second light transmission area, and the light reflecting layer of the light transmission module, such that the first light and the second light from different directions are allowed to be simultaneously received by the first sensing area and the second sensing area of the imaging sensor, and images on different directions are allowed to be sensed simultaneously.

In order to make the aforementioned features and advantages of the invention more comprehensible, embodiments accompanying figures are described in details below.

### BRIEF DESCRIPTION OF THE DRAWINGS

FIG. 1 is a schematic view illustrating an image sensing apparatus according to an embodiment of the invention.

FIGS. 2A and 2B are schematic views of a light transmission module according to an embodiment of the invention.

FIGS. 3A-3F are schematic views illustrating an image sensing apparatus according to another embodiment of the invention.

FIG. 4 is a schematic view illustrating of an interactive video system according to an embodiment of the present invention.

### DESCRIPTION OF EMBODIMENTS

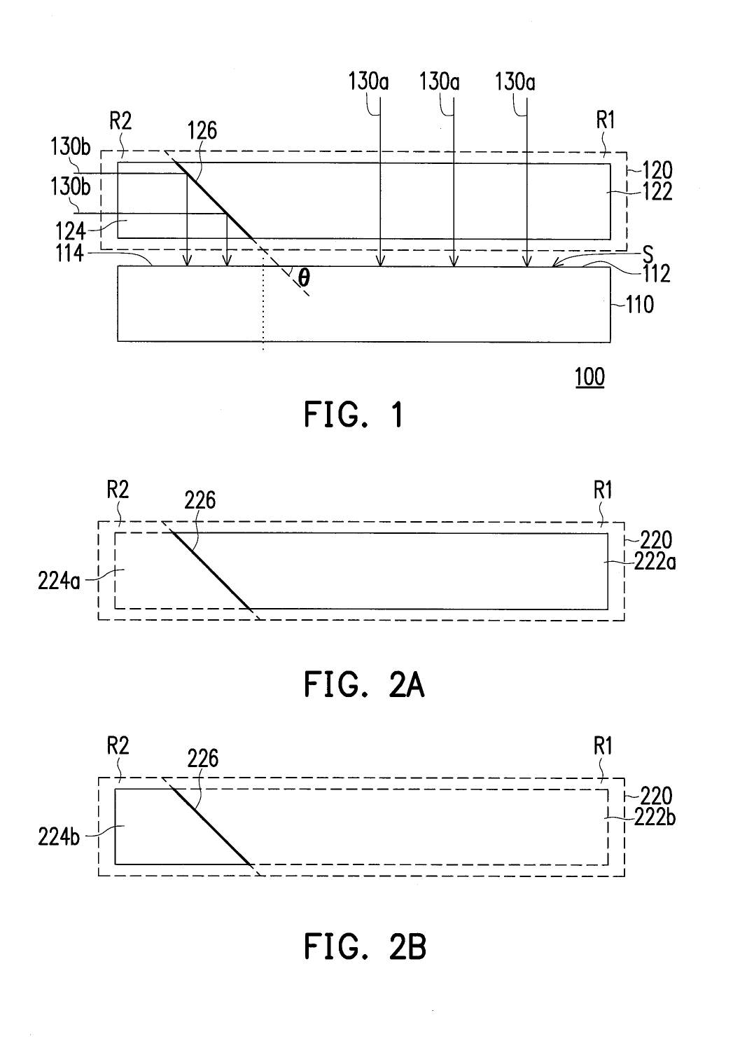

FIG. 1 is a schematic view illustrating an image sensing apparatus according to an embodiment of the invention. Referring to FIG. 1, an image sensing apparatus 100 of this embodiment includes an image sensor 110 and a light transmission module 120. The image sensor 110 has an active surface S including a first sensing area 112 and a second sensing area 114. The light transmission module 120 is disposed over the active surface S, and has a first light transmission area R1 and a second light transmission area R2. A first light 130a is allowed to penetrate through the first light transmission area R1 and received by the first sensing area 112. A second light 130b is reflected by the second light transmission area R2 and received by the second sensing area 114.

The active surface S of the image sensor 110 is able to sense an image. The first light 130a and the second light 130b transmitted through the light transmission module 120 respectively form an individual image at the first sensing area 112 and the second sensing area 114 of the active surface S. In this embodiment, the image sensor 110 includes a charge couple device (CCD), a complementary metal oxide semiconductor (CMOS) image sensor, or other electronic devices that are able to sense an image.

The light transmission module 120 is disposed over the active surface S, and the light transmission module 120 is directly or indirectly disposed over the active surface S of the image sensor 110. For example, the light transmission module 120 is adhered to the active surface S of the image sensor 110 through an optically clear Adhesive (OCA) or the like. In other words, the light transmission module 120 is disposed on top side of the active surface S of the image sensor 110. In this embodiment, the light transmission module 120 includes a first medium 122, a second medium 124, and a light reflecting layer 126, wherein the first medium 122 is disposed in the first light transmission area R1, the second medium 124 is disposed in the second light transmission area R2, and the light reflecting layer 126 is positioned between the first light transmission area R1 and the second light transmission area R2.

In the light transmission module 120, when the first light 130a penetrates through the first light transmission area R1, the first light 130a substantially penetrates through the first medium 122 and is transmitted to the first sensing area 112. When the second light 130b is reflected by the second light transmission area R2, the second light 130b substantially penetrates through the second medium 124 and is transmitted to the second sensing area 114. In an embodiment of the invention, the light reflecting layer 126 tilts at an angle θ relative to the active surface S, and the angle θ is not a right angle. When the second light 130b is reflected by the second light transmission area R2, the second light 130b is reflected to the second sensing area 114 of the active surface S through the light reflecting layer 126 because the light reflecting layer 126 tilts relative to the active surface S. It should be noted that, the first light 130a and the second light 130b enter the light transmission module 120 along different directions, for example. Thus, the light transmission module 120 is capable of receiving lights from different directions. In addition, the light transmission module 120 is capable of guiding lights from different directions to different sensing areas (i.e. the first sensing area 112 and the second sensing area 114) of the single image sensor 110.

Referring to FIG. 1, in this embodiment, a transmitting direction of the first light 130a is, for example, perpendicular to the active surface S of the image sensing apparatus 100, and a transmitting direction of the second light 130b is, for example, parallel to the active surface S of the image sensing apparatus 100. In order for the active surface S of the image sensor 110 to be able to receive the second light 130b, in the second light transmission area R2, the light reflecting layer 126 having the angle θ of tilting relative to the active surface S is used to reflect the second light 130b. Thereby, the second light 130b is received by the second sensing area 114 in the active surface S. However, the invention is not limited thereto. In other words, people skilled in the art may make the light transmission module 120 able to transmit three or even more types of lights from different directions by disposing a plurality of reflecting layers.

The light reflecting layer 126 of the light transmission module 120 is a light reflecting coating or a reflector, for example. The light reflecting layer 126 is coated on the first medium 122 or the second medium 124. In this embodiment, the first medium 122 of the light transmission module 120 is chosen from solid mediums and gaseous mediums. The second medium 124 is also chosen from solid mediums and gaseous mediums. For example, the solid medium is a glass, and the gaseous medium is air, but the choice is not limited thereto.

FIGS. 2A and 2B are schematic views of a light transmission module according to an embodiment of the invention. Referring to FIG. 2A, in a light transmission module 220 in FIG. 2A, a first medium 222a is a solid medium, and a second medium 224a is a gaseous medium (e.g. air).

Referring to FIG. 2B, in the light transmission module 220 in FIG. 2B, a first medium 222b is a gaseous medium (e.g. air), and a second medium 224b is a solid medium. Since the first medium and the second medium may be different types of medium, in application, the types of medium may be appropriately adjusted in accordance with a manufacturing process and need of the image sensing apparatus 100.

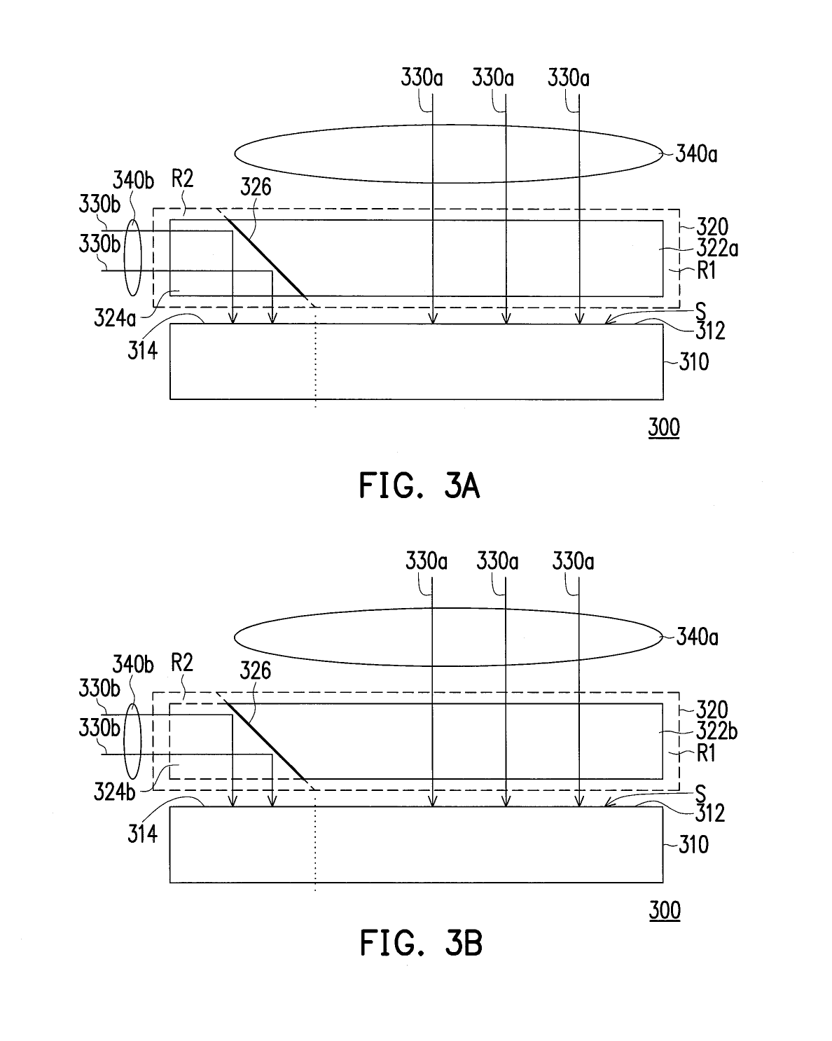

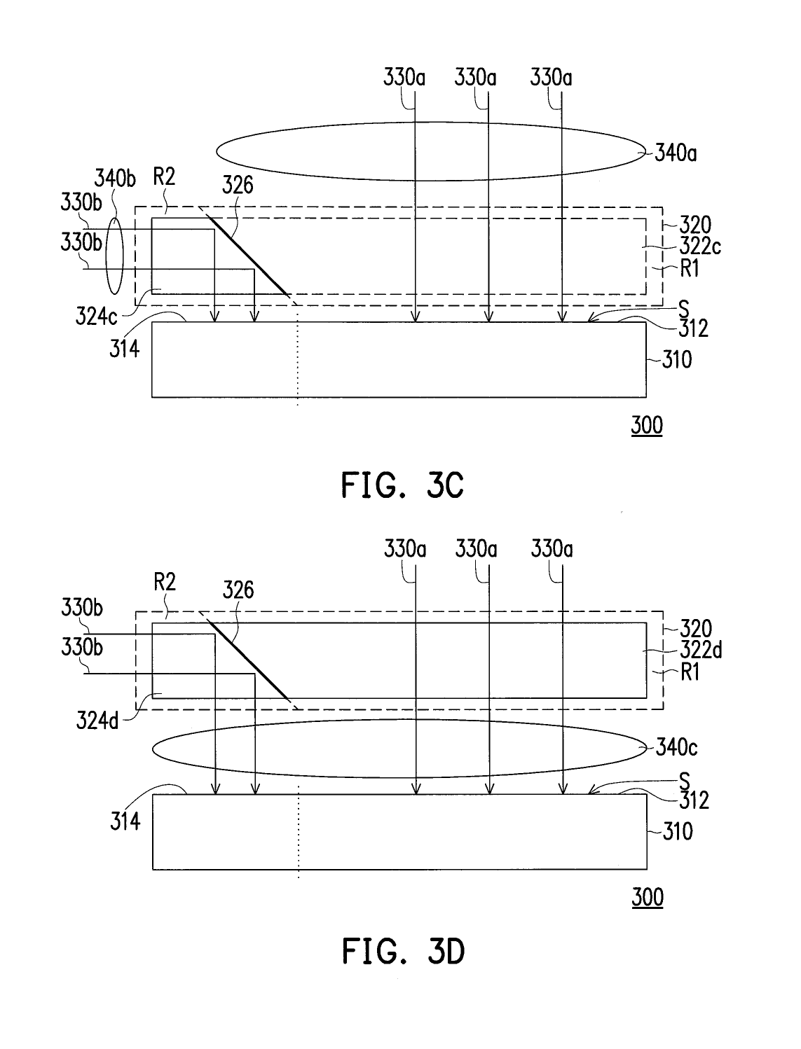

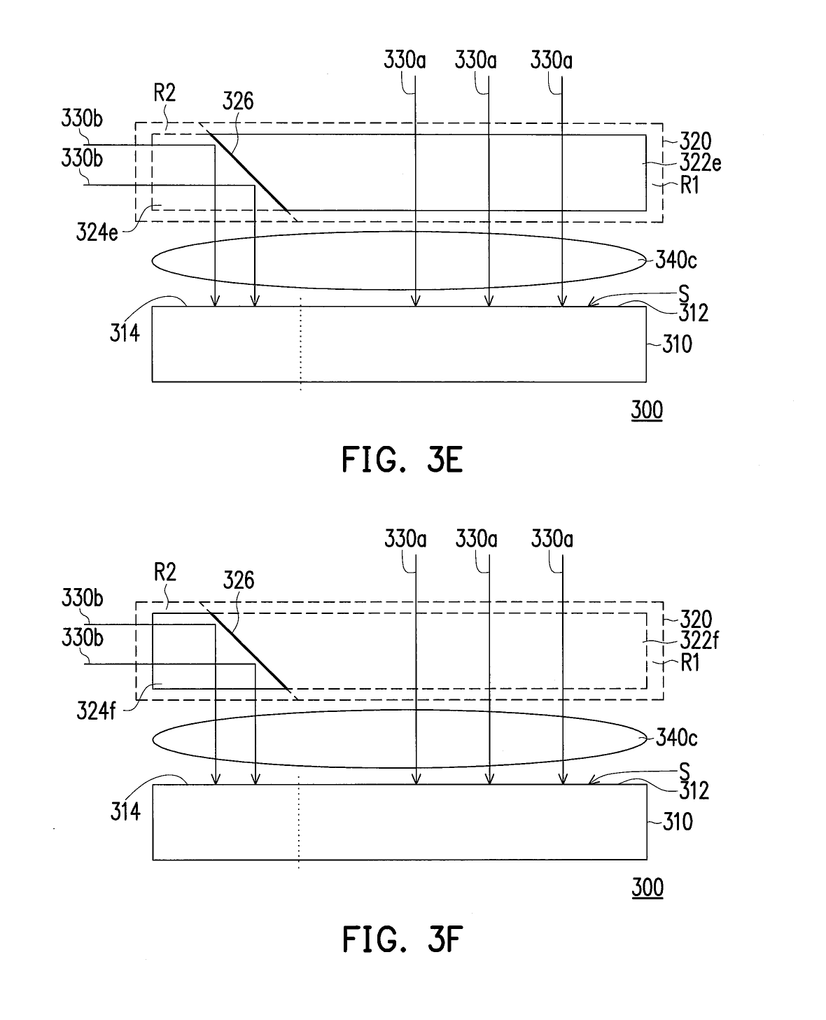

FIGS. 3A-3F are schematic views illustrating an image sensing apparatus according to another embodiment of the invention, wherein a structure of a light transmission module 320, a structure of an image sensor 310, and a relative structural disposition of the light transmission module 320 and the image sensor 310 are the same as the light transmission module 120 and the image sensor 110, so details of these respects are not reiterated herein. Referring to FIG. 3A, the image sensing apparatus of this embodiment further includes a lens set 340a and a lens set 340b, wherein the lens set 340a is disposed on a transmitting path of a first light 330a, and the light transmission module 320 is positioned between the lens set 340a and the image sensor 310. In addition, the lens set 340b is disposed on a transmitting path of a second light 330b, and a second medium 324a is positioned between the lens set 340b and a light reflecting layer 326. The lens sets 340a and 340b are respectively used to condense the first light 330a and the second light 330b to optimize an image quality of the first light 330a and the second light 330b on a first sensing area 312 and a second sensing area 314.

As illustrated in FIG. 3A, a first medium 322a and a second medium 324a in the light transmission module 320 are both solid mediums. As illustrated in FIG. 3B, a first medium 322b in the light transmission module 320 is a solid medium, and a second medium 324b in the light transmission module 320 is a gaseous medium (e.g. air,). As illustrated in FIG. 3C, a first medium 322c in the light transmission module 320 is a gaseous medium (e.g. air), and a second medium 324c in the light transmission module 320 is a solid medium. A location at which the lens set is disposed in the invention may be modified according to the requirement of design in practice.

Referring to FIG. 3D, in this embodiment, a lens set 340c is disposed between the image sensor 310 and the light transmission module 320, and the lens set 340c is positioned on the transmitting path of the first light 330a and the transmitting path of the second light 330b. The lens set 340c condenses the first light 330a and the second light 330b simultaneously to optimize an image quality of the first light 330a and the second light 330b on the first sensing area 312 and the second sensing area 314. As illustrated in FIG. 3D, a first medium 322d and a second medium 324d in the light transmission module 320 are both solid mediums. As illustrated in FIG. 3E, a first medium 322e in the light transmission module 320 is a solid medium, and a second medium 324e in the light transmission module 320 is a gaseous medium (e.g. air). As illustrated in FIG. 3F, a first medium 322f in the light transmission module 320 is a gaseous medium (e.g. air), and a second medium 324f in the light transmission module 320 is a solid medium.

According to the embodiment, the light transmission module is capable of transmitting a plurality of types of light from different directions simultaneously and forming a plurality of images on the image sensor. Based on this characteristic, the image sensing apparatus provided in the invention is suitable for a system that senses images from a plurality of directions, such as an interactive video system having a 2D optical touch-control function and a 3D optical recognition function.

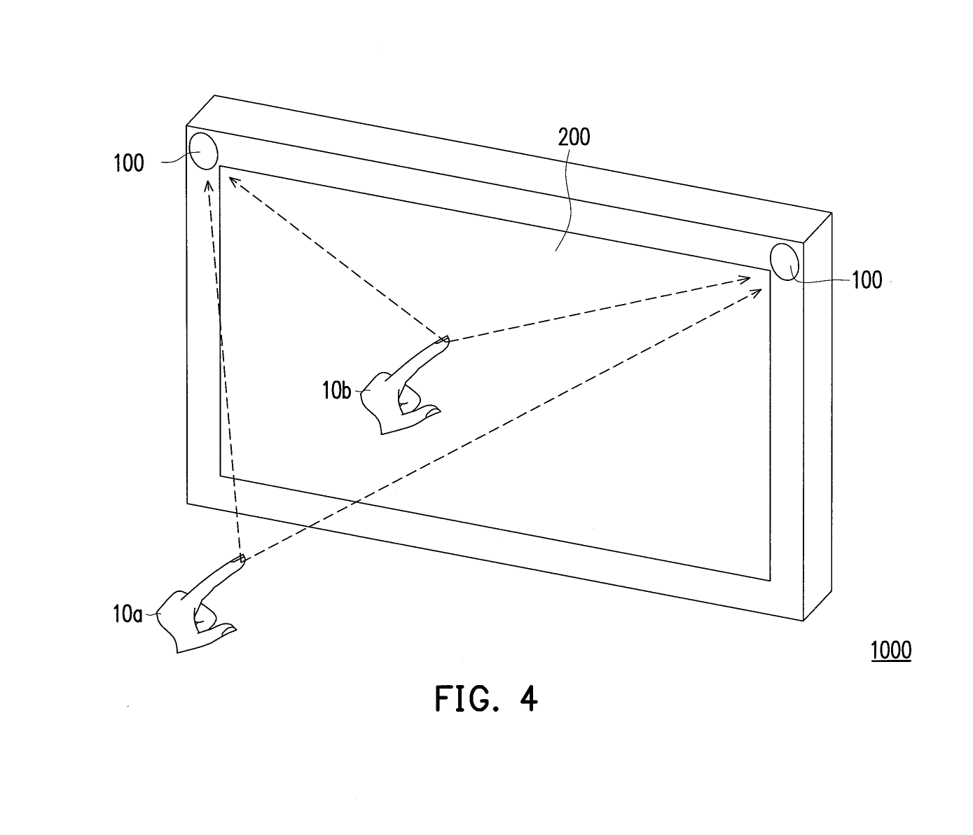

FIG. 4 is a schematic view illustrating an interactive video system according to an embodiment of the invention. Referring to FIG. 4, an interactive video system 1000 of this embodiment includes a display screen 200 and the aforesaid image sensing apparatus 100. Also, the image sensing apparatus 100 is disposed next to the display screen 200. As illustrated in FIGS. 1 and 4, when a user intends to use his/her finger to operate the interactive video system 1000, a finger 10a of the user located in front of the display screen 200 and being kept a distance from the display screen 200, the image sensing apparatus 100 senses an image of the finger 10a via the first sensing area 112. At this point, the first light 130a is transmitted to the first sensing area 112 through the first light transmission area R1 and forms the image of the finger 10a on the active surface S. The interactive video system 1000 recognizes the image in the first sensing area 112 to determine a location and a gesture of the finger 10a, so that the 3D optical recognition function is realized.

When the user's finger 10b touches the display screen 200, the image sensing apparatus 100 senses an image of the finger 10b via the second sensing area 114. At this point, the second light 130b is transmitted to the second sensing area 114 through the second light transmission area R2. During transmission of the second light 130b, the second light transmission area R2 reflects the second light 130b via the light reflecting layer 126 in order for the second light 130b to be received by the second sensing area 114, such that the image of the finger 10b is formed on the active surface S. Since an image formed on the second sensing area 114 is just a planar (2D) image, the image is usually used for a positioning purpose. The interactive video system 1000 uses the image sensed in the second sensing area 114 to determine the location at which the finger 10b touches on the display screen 200, thereby recognizing the user's intention and making a response accordingly. When realizing the 2D optical touch-control function on the interactive video system 1000, two or more image sensing apparatus 100 may be used to assist positioning. A quantity and a location of disposition of the image sensing apparatus may be modified according to the requirement of design in practice.

The interactive video system 1000 determines whether to activate the 2D optical touch-control function or the 3D optical recognition function according to whether there is a featured image in the sensed image. According to the previous embodiment, the interactive video system 1000 performs recognition based on a finger image. When the image sensing apparatus 100 receives the first light 130a and the second light 130b simultaneously and forms an image at the first sensing area 112 and the second sensing area 114, in the event that the image in the first sensing area 112 and the image at the second sensing area 114 are both featured images, the interactive video system 1000 processes the image in the second sensing area 140 with priority and activates the 2D optical touch-control function. In other situations, the interactive video system 1000 determines whether to activate the 2D optical touch-control function or the 3D optical recognition function according to the area at which the featured image is formed.

In conclusion, the image sensing apparatus provided by the embodiments of the invention transmits lights from different directions via the light transmission module in the image sensing apparatus to sense images from a plurality of directions simultaneously. The image sensing apparatus of the invention is simple in structure, compact, and the manufacturing cost is effectively reduced.

Although the present invention has been described with reference to the above embodiments, it is not intended to limit the invention. It is apparent to one of the ordinary skill in the art that modifications to the described embodiments may be made without departing from the spirit of the invention. Accordingly, the scope of the invention will be defined by the attached claims and not by the above detailed descriptions.

What is claimed is:

1. An image sensing apparatus, comprising:
an image sensor, comprising an active surface, wherein the active surface comprises a first sensing area and a second sensing area; and
a light transmission module, disposed over the active surface and having a first light transmission area and a second light transmission area, wherein a first light is allowed to penetrate through the first light transmission area and received by the first sensing area, and a second light is reflected by the second light transmission area and received by the second sensing area.

2. The image sensing apparatus according to claim 1, wherein the light transmission module comprising:
a first medium, disposed in the first light transmission area;
a second medium, disposed in the second light transmission area; and
a light reflecting layer, positioned between the first light transmission area and the second light transmission area.

3. The image sensing apparatus according to claim 2, wherein the second light transmission area reflects the second light via the light reflecting layer in order for the second light to be received by the second sensing area.

4. The image sensing apparatus according to claim 2, wherein the light reflecting layer tilts at an angle relative to the active surface, and the angle is not a right angle.

5. The image sensing apparatus according to claim 2, wherein the light reflecting layer is a light reflecting coating.

6. The image sensing apparatus according to claim 2, wherein the first medium comprises a solid medium or a gaseous medium, and the second medium comprises a solid medium or a gaseous medium.

7. The image sensing apparatus according to claim 2 further comprising:
a lens set, disposed on a transmitting path of the second light, wherein the second medium is positioned between the lens set and the light reflecting layer.

8. The image sensing apparatus according to claim 1 further comprising:
a lens set, disposed on a transmitting path of the first light, and the light transmission module is positioned between the lens set and the image sensor.

9. The image sensing apparatus according to claim 1 further comprising:
a lens set, disposed between the image sensor and the light transmission module and positioned on transmitting paths of the first light and the second light.

10. The image sensing apparatus according to claim 1, wherein the image sensor comprises a charge coupled device or a complementary metal oxide semiconductor image sensor.
